(19) United States
(12) Patent Application Publication
(10) Pub. No.: US 2026/0020433 A1
(43) Pub. Date: Jan. 15, 2026

(54) LIGHT EMITTING DIODE AND DISPLAY DEVICE INCLUDING THE SAME

(71) Applicant: Samsung Display Co., LTD., Yongin-si (KR)

(72) Inventors: JONGWON LEE, Yongin-si (KR); SEUNG CHEOL KIM, Yongin-si (KR); KA-YOUNG LEE, Yongin-si (KR); Chang-Min LEE, Yongin-si (KR); HAKCHOONG LEE, Yongin-si (KR); Jae Hoon HWANG, Yongin-si (KR)

(21) Appl. No.: 19/199,824

(22) Filed: May 6, 2025

(30) Foreign Application Priority Data
Jul. 9, 2024 (KR) 10-2024-0090261

(51) Int. Cl. H10K 50/13; H10K 59/38

(52) U.S. Cl. CPC H10K 50/13; H10K 59/38

(57) ABSTRACT

A light emitting diode includes: a first electrode; a second electrode disposed opposite to the first electrode; and a plurality of light emitting layers disposed between the first electrode and the second electrode, and the light emitting layers include one red-light emitting layer, two green-light emitting layers, and two blue-light emitting layers.

This application claims priority to Korean Patent Application No. 10-2024-0090261, filed on Jul. 9, 2024, and all the benefits accruing therefrom under 35 U.S.C. § 119, the content of which in its entirety is herein incorporated by reference.

### BACKGROUND

### (a) Field

Embodiments of the disclosure relate to a light emitting diode and a display device including the light emitting diode.

### (b) Description of the Related Art

A light emitting diode typically includes an anode, a cathode, and a light emitting layer formed therebetween, a hole injected from the anode and an electron injected from the cathode combine in the light emitting layer to generate an exciton, and the exciton falls from an excited state to a ground state to generate light.

Light emitting diodes may be driven by low voltage, may be lightweight and thin, and may have desired characteristics such as viewing angle, contrast, and response speed, such that light emitting didoes are widely used in various electronic devices.

### SUMMARY

Embodiments provide a light emitting diode having improved light emitting efficiency and a display device including the light emitting diode.

A light emitting diode according to an embodiment includes: a first electrode; a second electrode that faces the first electrode; and a plurality of light emitting layers that are disposed between the first electrode and the second electrode, and the light emitting layers include one red-light emitting layer, two green-light emitting layers, and two blue-light emitting layers.

In an embodiment, the light emitting layers may be stacked in an order of the one red-light emitting layer, one of the two blue-light emitting layers, one of the two green-light emitting layers, the other of the two blue-light emitting layers, and the other of the two green-light emitting layers between the first electrode and the second electrode.

In an embodiment, the light emitting layers may be stacked in an order of one of the two blue-light emitting layers, the other of the one red-light emitting layers, one of the two green-light emitting layer, the two blue-light emitting layers, and the two green-light emitting layers between the first electrode and the second electrode.

In an embodiment, the light emitting layers may be stacked in an order of one of the two blue-light emitting layers, the other of the two blue-light emitting layers, one of the two green-light emitting layers, the one red-light emitting layer, and the other of the two green-light emitting layers between the first electrode and the second electrode.

In an embodiment, an entire thickness of all layers disposed between the first electrode and the second electrode may be in a range of about 3800 angstrom (Å) to about 4800 Å.

A display device according to an embodiment includes: a color conversion panel; and a display panel disposed to overlap the color conversion panel, and the display panel includes a first substrate and a plurality of light emitting diodes disposed above the first substrate, the color conversion panel includes a first color conversion layer, a second color conversion layer, and a transmission layer which are disposed to overlap the light emitting diodes, respectively, the transmission layer does not include a scatterer, each of the light emitting diodes includes a first electrode, a second electrode disposed opposite to the first electrode, and a plurality of light emitting layers disposed between the first electrode and the second electrode, and the light emitting layers include one red-light emitting layer, two green-light emitting layers, and two blue-light emitting layers.

In an embodiment, the light emitting layers may be stacked in an order of the one red-light emitting layer, one of the two blue-light emitting layers, one of the two green-light emitting layers, the other of the two blue-light emitting layers, and the other of the two green-light emitting layers between the first electrode and the second electrode.

In an embodiment, the light emitting layers may be stacked in an order of one of the two blue-light emitting layers, the one red-light emitting layer, one of the two green-light emitting layers, the other of the two blue-light emitting layers, and the other of the two green-light emitting layers between the first electrode and the second electrode.

In an embodiment, the light emitting layers may be stacked in an order of one of the two blue-light emitting layers, the other of the two blue-light emitting layers, one of the two green-light emitting layers, the one red-light emitting layer, and the other of the two green-light emitting layers between the first electrode and the second electrode.

In an embodiment, an entire thickness of all layers disposed between the first electrode and the second electrode may be in a range of about 3800 Å to about 4800 Å.

In an embodiment, the color conversion panel may include a blue color filter, a red color filter, and a green color filter which are disposed to overlap the light emitting diodes, respectively.

In an embodiment, thicknesses of first electrodes of the light emitting diodes which overlap the blue color filter, the red color filter, and the green color filter, respectively, may be different from each other.

In an embodiment, each of the light emitting diodes may further include a hole transport layer and a hole injection layer, and thicknesses of the hole transport layers and the hole injection layers of the light emitting diodes which overlap the blue color filter, the red color filter, and the green color filter, respectively, may be different from each other.

A display device according to another embodiment includes: a color conversion panel; and a display panel disposed to overlap the color conversion panel, and the display panel includes a first substrate and a plurality of light emitting diodes disposed above the first substrate, the color conversion panel includes a first color conversion layer, a second color conversion layer, and a transmission layer which are disposed to overlap the light emitting diodes, respectively, each of the light emitting diodes include a first electrode, a second electrode disposed opposite to the first electrode, and a plurality of light emitting layers disposed between the first electrode and the second electrode, and the light emitting layers include one red-light emitting layer, two green-light emitting layers, and two blue-light emitting layers.

In an embodiment, the light emitting layers may be stacked in an order of the one red-light emitting layer, one of the two blue-light emitting layers, one of the two green-light emitting layers, the other of the two blue-light emitting layers, and the other of the two green-light emitting layers between the first electrode and the second electrode.

In an embodiment, the light emitting layers may be stacked in an order of one of the two blue-light emitting layers, the one red-light emitting layer, one of the two green-light emitting layers, the other of the two blue-light emitting layers, and the other of the two green-light emitting layers between the first electrode and the second electrode.

In an embodiment, the light emitting layers may be stacked in an order of one of the two blue-light emitting layers, the other of the two blue-light emitting layers, one of the two green-light emitting layers, the one red-light emitting layer, and the other of the two green-light emitting layers between the first electrode and the second electrode.

In an embodiment, an entire thickness of all layers disposed between the first electrode and the second electrode may be in a range of about 3800 Å to about 4800 Å.

In an embodiment, thicknesses of first electrodes of the light emitting diodes which overlap the first color conversion layer, the second color conversion layer, and the transmission layer, respectively, may be different from each other. In an embodiment, each of the light emitting diodes may further include a hole transport layer and a hole injection layer, and thicknesses of hole transport layers and hole injection layers of the light emitting diodes which overlap the first color conversion layer, the second color conversion layer, and the transmission layer, respectively, may be different be different from each other.

According to embodiments of the disclosure, a light emitting diode and a display device including the light emitting diode may have improved light emitting efficiency.

### BRIEF DESCRIPTION OF THE DRAWINGS

FIG. 1 schematically shows a cross-section of a light emitting diode according to an embodiment.

FIG. 2 schematically shows a color in which a light emitting layer of each light emitting element emits light in a light emitting diode according to an embodiment.

FIG. 3 schematically shows a color in which a light emitting layer of each light emitting element emits light in a light emitting diode according to an embodiment.

FIG. 4 schematically shows a color in which a light emitting layer of each light emitting element emits light in a light emitting diode according to an embodiment.

FIG. 5 shows a cross-section of a display device according to an embodiment.

FIG. 6 shows a cross-section of a display device according to an embodiment.

FIG. 7 shows a cross-section of a display device according to an embodiment.

FIG. 8 shows a cross-section of a display device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In order to clearly describe the disclosure, parts or portions that are irrelevant to the description are omitted, and identical or similar constituent elements throughout the specification are denoted by the same reference numerals.

In the drawings, a size and a thickness of each element are arbitrarily illustrated for ease of description, and the disclosure is not necessarily limited to those illustrated in the drawings. In the drawings, the thicknesses of some layers and areas are exaggerated for clarity. In the drawings, for ease of description, the thicknesses of some layers and areas are exaggerated.

It should be understood that when an element such as a layer, a film, a region, or a plate is referred to as being “on” or “above” another element, it may be directly on the other element, or an intervening element may also be present therebetween. In contrast, when an element is referred to as being “directly on” another element, there is no intervening element present. Further, in the specification, the word “on” or “above” means disposed on or below a referenced part, and does not necessarily mean disposed on the upper side of the referenced part based on a gravitational direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a light emitting diode (or a light emitting element) and a display device including the light emitting diode according to embodiments will be described in detail with reference to the accompanying drawings.

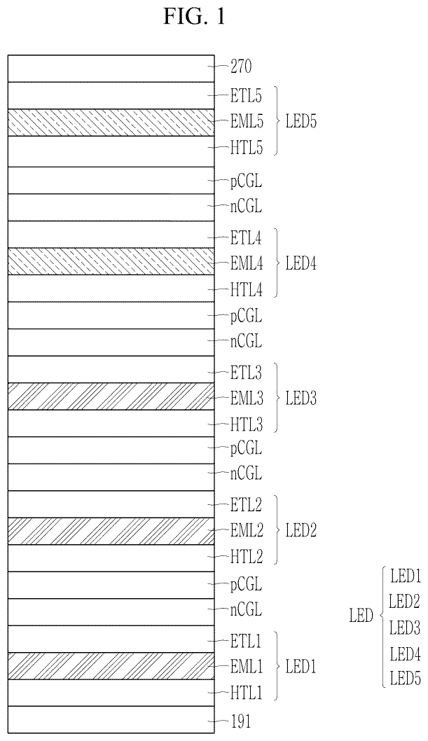

FIG. 1 schematically shows a cross-section of a light emitting diode according to an embodiment.

Referring to FIG. 1, the light emitting diode according to an embodiment may include a plurality of light emitting diodes LED1, LED2, LED3, LED4, and LED5 disposed between a first electrode 191 and a second electrode 270.

In an embodiment, as shown in FIG. 1, each light emitting diode LED1, LED2, LED3, LED4, and LED5 may include a hole transport layer HTL, a light emitting layer EML, and an electron transport layer ETL. That is, the first light emitting diode LED1 may include a first hole transport layer HTL1, a first light emitting layer EML1, and a first electron transport layer ETL1. Likewise, the second light emitting diode LED2 may include a second hole transport layer HTL2, a second light emitting layer EML2, and a second electron transport layer ETL2, the third light emitting diode LED3 may include a third hole transport layer HTL3, a third light emitting layer EML3, and a third electron transport layer ETL3, and the fourth light emitting diode LED4 may include a fourth hole transport layer HTL4, a fourth light emitting layer EML4, and a fourth electron transport layer ETL4. In such an embodiment, the fifth light emitting diode LED5 may include a fifth hole transport layer HTL5, a fifth light emitting layer EML5, and a fifth electron transport layer ETL5.

An n-type charge generation layer nCGL and a -type charge generation layer pCGL may be disposed between the light emitting diodes LED1, LED2, LED3, LED4, and LED5. Although not shown in FIG. 1, an electron blocking layer may be disposed between the hole transport layer HTL and the light emitting layer EML, and a hole blocking layer may be disposed between the electron transport layer ETL and the light emitting layer EML. In addition, other layers not shown in FIG. 1 may be disposed.

In an embodiment, one light emitting diode of the light emitting diodes LED1, LED2, LED3, LED4, and LED5 may emit red light, two light emitting diodes of the light emitting diodes LED1, LED2, LED3, LED4, and LED5 may emit green light, and two light emitting diodes of the light emitting diodes LED1, LED2, LED3, LED4, and LED5 may emit blue light. That is, the light emitting diode according to an embodiment may have a structure in which one red-light emitting diode, two green-light emitting diodes, and two blue-light emitting diodes are stacked. This will be described in detail later, but the light emitting diode according to an embodiment may have the stacked structure, thus improving light emitting efficiency of the light emitting diode and the display device to which this light emitting diode is applied.

In an embodiment, the first light emitting diode LED1 may emit red light, the second light emitting diode LED2 may emit blue light, the third light emitting diode LED3 may emit green light, the fourth light emitting diode LED4 may emit blue light, and the fifth light emitting diode LED5 may emit green light. In such an embodiment, light emitting layers that emit red light, blue light, green light, blue light, and green light, respectively, may be sequentially stacked between the first electrode 191 and the second electrode 270. However, this is only an example, and the disclosure is not limited thereto.

In an embodiment, an entire thickness of all layers disposed between the first electrode 191 and the second electrode 270 may be in a range of about 3800 angstrom (Å) to about 4800 Å. This is a thickness range where a fourth resonance of blue light may occur between the first electrode 191 and the second electrode 270.

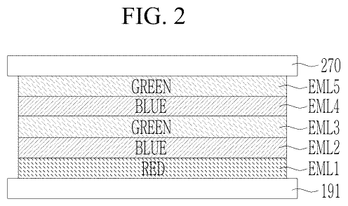

FIG. 2 schematically shows a color of light to be emitted from a light emitting layer of each light emitting diode EML1, EML2, EML3, EML4, or EML5 according to an embodiment. As shown in FIG. 2, in the display device according to the embodiment, the light emitting layers that emit red light, blue, green light, blue light, and green light, respectively, may be sequentially stacked between the first electrode 191 and the second electrode 270. However, this is only an example, and the color of light emitting from the light emitting layer may vary.

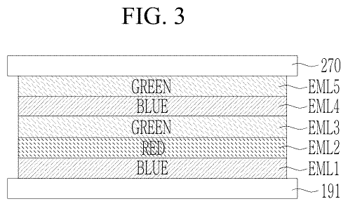

FIG. 3 schematically shows a color of light being to be from a light emitting layer of each light emitting diode EML1, EML2, EML3, EML4, or EML5 according to another embodiment. As shown in FIG. 3, in the display device according to the embodiment, light emitting layers that emit blue light, red light, green light, blue light, and green light, respectively, may be sequentially stacked between the first electrode 191 and the second electrode 270.

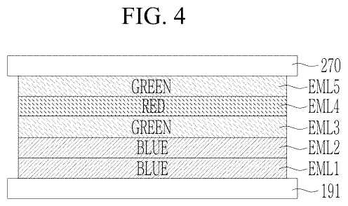

FIG. 4 schematically shows a color of light being emitted from a light emitting layer of each light emitting diode EML1, EML2, EML3, EML4, or EML5 according to another embodiment. As shown in FIG. 4, in the display device according to the embodiment, light emitting layers that emit blue light, blue light, green light, red light, and green light, respectively, may be sequentially stacked between the first electrode 191 and the second electrode 270.

Various embodiments are shown in FIGS. 2 to 4, but these are only examples, and the disclosure is not limited thereto.

The light emitting diode according to an embodiment may include five light emitting layers, and the five light emitting layers may include one red-light emitting layer, two green-light emitting layers, and two blue-light emitting layers. The light emitting diode having the stacking structure may have improved light emitting efficiency compared with a conventional light emitting diode, e.g., a light emitting diode including two green-light emitting layers and three blue-light emitting layers. Hereinafter, an effect of the light emitting diode according to the embodiment of the disclosure will be described through a specific experimental example.

The following Table 1 shows a stacking configuration of the light emitting diode according to an embodiment. Table 1 shows a material, a thickness, and a doping concentration included in each layer constituting the light emitting diode LED1, LED2, LED3, LED4, or LED5. However, this is only an example, and the disclosure is not limited thereto.

TABLE 1

| | | | | Doping |
|---|---|---|---|---|
| | | | | concentration |
| Layer | | Material name | Thickness (Å) | (%) |
| Second electrode | | CPL | 500 | |
| | | AgMg | 100 | 10 |
| | | Yb | 10 | |
| LED5 | Fifth electron | TPM-TAZ + Liq | 570 | 50 |
| | transport layer | | | |
| | Fifth light emitting | GH_HT:GH_ET 1:1 + | 250 | 9 |
| | layer (green) | GD | | |
| | Fifth hole transport | NPB | 300 | |
| | layer | | | |
| | Fifth hole injection | HATCN | 50 | |
| | layer | | | |
| CGL | | BCP + Li | 65 | 10 |
| LED4 | Fourth electron | TPM-TAZ + Liq | 100 | 50 |
| | transport layer | | | |
| | Fourth hole | T2T | 50 | |
| | blocking layer | | | |
| | Fourth light | BH1 (or BH2) + BD | 85 | 1 |
| | emitting layer | | | |
| | (blue) | | | |
| | Fourth electron | TCTA | 75 | |
| | blocking layer | | | |
| | Fourth hole | NPB | 20 | |
| | transport layer | | | |
| | Fourth hole | HATCN | 50 | |
| | injection layer | | | |
| CGL | | BCP + Li | 65 | 10 |
| LED3 | Third electron | TPM-TAZ + Liq | 100 | 50 |
| | transport layer | | | |
| | Third light emitting | GH_HT:GH_ET 1:1 + | 200 | 9 |
| | layer (green) | GD | | |
| | Third hole | NPB | 85 | |
| | transport layer | | | |
| | Third hole injection | HATCN | 50 | |
| | layer | | | |
| CGL | | BCP + Li | 65 | 10 |
| LED2 | Second electron | TPM-TAZ + Liq | 100 | 50 |
| | transport layer | | | |
| | Second hole | T2T | 50 | |
| | blocking layer | | | |
| | Second light | BH1 (or BH2) + BD | 85 | 1 |
| | emitting layer | | | |
| | (blue) | | | |
| | Second electron | TCTA | 75 | |
| | blocking layer | | | |
| | Second hole | NPB | 370 | |
| | transport layer | | | |
| | Second hole | HATCN | 50 | |
| | injection layer | | | |
| CGL | | BCP + Li | 65 | 10 |
| LED1 | First electron | TPM-TAZ + Liq | 100 | 50 |
| | transport layer | | | |
| | First hole blocking | T2T | 50 | |
| | layer | | | |
| | First light emitting | RED Host:RED | 250 | |
| | layer (red) | Dopant | | |
| | First hole transport | NPB | 450 | |
| | layer | | | |
| | First hole injection | TAPC:HATCN | 50 | |
| | layer | | | |

| | | |
|---|---|---|
| First electrode | ITO/Ag/ITO | 70/800/70 |

In the light emitting diode according to the embodiment of Table 1, the first electrode, the red-light emitting layer, the blue-light emitting layer, the green-light emitting layer, the blue-light emitting layer, the green-light emitting layer, and the second electrode are sequentially stacked, and the structure may be referred to as an RBGBG stacking structure. Although the first electrode of the light emitting diode according to the embodiment of Table 1 has a same thickness as each other, a thickness of the first electrode of the light emitting diode according to another embodiment may vary according to a pixel included in each light emitting diode.

The following Table 2 shows a stacking configuration of the light emitting diode according to another embodiment. Table 2 shows a material, a thickness, and a doping concentration included in each layer constituting the light emitting diode LED1, LED2, LED3, LED4, or LED5. However, this is only an example, and the disclosure is not limited thereto.

TABLE 2

| | | | | Doping |
|---|---|---|---|---|
| | | | | concentration |
| Layer | | Material name | Thickness (Å) | (%) |
| Second electrode | | CPL | 500 | |
| | | AgMg | 100 | 10 |
| | | Yb | 10 | |
| LED5 | Fifth electron | TPM-TAZ + Liq | 570 | 50 |
| | transport layer | | | |
| | Fifth light emitting | GH_HT:GH_ET 1:1 + | 250 | 9 |
| | layer (green) | GD | | |
| | Fifth hole transport | NPB | 300 | |
| | layer | | | |
| | Fifth hole injection | HATCN | 50 | |
| | layer | | | |
| CGL | | BCP + Li | 65 | 10 |
| LED4 | Fourth electron | TPM-TAZ + Liq | 100 | 50 |
| | transport layer | | | |
| | Fourth hole | T2T | 50 | |
| | blocking layer | | | |
| | Fourth light | BH1 (or BH2) + BD | 85 | 1 |
| | emitting layer | | | |
| | (blue) | | | |
| | Fourth electron | TCTA | 75 | |
| | blocking layer | | | |
| | Fourth hole | NPB | 20 | |
| | transport layer | | | |
| | Fourth hole | HATCN | 50 | |
| | injection layer | | | |
| CGL | | BCP + Li | 65 | 10 |
| LED3 | Third electron | TPM-TAZ + Liq | 100 | 50 |
| | transport layer | | | |
| | Third light emitting | GH_HT:GH_ET 1:1 + | 200 | 9 |
| | layer (green) | GD | | |
| | Third hole | NPB | 85 | |
| | transport layer | | | |
| | Third hole injection | HATCN | 50 | |
| | layer | | | |
| CGL | | BCP + Li | 65 | 10 |
| LED2 | Second electron | TPM-TAZ + Liq | 100 | 50 |
| | transport layer | | | |
| | Second hole | T2T | 50 | |
| | blocking layer | | | |
| | Second light | BH1 (or BH2) + BD | 85 | 1 |
| | emitting layer | | | |
| | (blue) | | | |
| | Second electron | TCTA | 75 | |
| | blocking layer | | | |
| | Second hole | NPB | 370 | |
| | transport layer | | | |
| | Second hole | HATCN | 50 | |
| | injection layer | | | |
| CGL | | BCP + Li | 65 | 10 |
| LED1 | First electron | TPM-TAZ + Lig | 100 | 50 |
| | transport layer | | | |
| | First hole blocking | T2T | 50 | |
| | layer | | | |
| | First light emitting | RED Host:RED | 250 | |
| | layer (red) | Dopant | | |
| | First hole transport | NPB | 450 | |
| | layer | | | |
| | First hole injection | TAPC:HATCN | 50 | |
| | layer | | | |

| | | |
|---|---|---|
| First electrode | ITO/Ag/ITO | Green: |

70/800/70
Blue:
70/800/550
Red:
70/800/750

As shown in Table 2, a thickness of the first electrode of the light emitting diode may vary according to a pixel included in each light emitting diode. That is, the light emitting diode included in a green pixel may have the first electrode in which a thickness of ITO is 70 Å, a thickness of Ag is 800 Å, and a thickness of ITO is 70 Å, the light emitting diode included in a blue pixel may have the first electrode in which a thickness of ITO is 70 Å, a thickness of Ag is 800 Å, and a thickness of ITO is 550 Å, and the light emitting diode included in a red pixel may have the first electrode in which a thickness of ITO is 70 Å, a thickness of Ag is 800 Å, and a thickness of ITO is 750 Å. By varying a thickness of the first electrode for each pixel as described above, an optimal resonance thickness for each pixel may be derived. In addition, in Table 2, the optimal resonance thickness is adjusted by varying the thickness of the first electrode for each pixel, but in another embodiment, the optimal resonance thickness for each pixel may be derived by varying a thickness of the first hole transport layer for each pixel.

The following Table 3 shows a stacking configuration of the light emitting diode according to another embodiment. Table 3 shows a material, a thickness, and a doping concentration included in each layer constituting the light emitting diode LED1, LED2, LED3, LED4, or LED5. However, this is only an example, and the disclosure is not limited thereto.

TABLE 3

| | | | | Doping |
|---|---|---|---|---|
| | | | | concentration |
| Layer | | Material name | Thickness (Å) | (%) |
| Second electrode | | CPL | 500 | |
| | | AgMg | 100 | 10 |
| | | Yb | 10 | |
| LED5 | Fifth electron | TPM-TAZ + Liq | 570 | 50 |
| | transport layer | | | |
| | Fifth light emitting | GH_HT:GH_ET 1:1 + | 250 | 9 |
| | layer (green) | GD | | |
| | Fifth hole transport | NPB | 300 | |
| | layer | | | |
| | Fifth hole injection | HATCN | 50 | |
| | layer | | | |
| CGL | | BCP + Li | 65 | 10 |
| LED4 | Fourth electron | TPM-TAZ + Liq | 100 | 50 |
| | transport layer | | | |
| | Fourth hole | T2T | 50 | |
| | blocking layer | | | |
| | Fourth light | BH1 (or BH2) + BD | 85 | 1 |
| | emitting layer | | | |
| | (blue) | | | |
| | Fourth electron | TCTA | 75 | |
| | blocking layer | | | |
| | Fourth hole | NPB | 20 | |
| | transport layer | | | |
| | Fourth hole | HATCN | 50 | |
| | injection layer | | | |
| CGL | | BCP + Li | 65 | 10 |
| LED3 | Third electron | TPM-TAZ + Liq | 100 | 50 |
| | transport layer | | | |
| | Third light emitting | GH_HT:GH_ET 1:1 + | 200 | 9 |
| | layer (green) | GD | | |
| | Third hole | NPB | 85 | |
| | transport layer | | | |
| | Third hole injection | HATCN | 50 | |
| | layer | | | |
| CGL | | BCP + Li | 65 | 10 |
| LED2 | Second electron | TPM-TAZ + Liq | 100 | 50 |
| | transport layer | | | |
| | Second hole | T2T | 50 | |
| | blocking layer | | | |
| | Second light | BH1 (or BH2) + BD | 85 | 1 |
| | emitting layer | | | |
| | (blue) | | | |
| | Second electron | TCTA | 75 | |
| | blocking layer | | | |
| | Second hole | NPB | 370 | |
| | transport layer | | | |
| | Second hole | HATCN | 50 | |
| | injection layer | | | |
| CGL | | BCP + Li | 65 | 10 |
| LED1 | First electron | TPM-TAZ + Liq | 100 | 50 |
| | transport layer | | | |
| | First hole blocking | T2T | 50 | |
| | layer | | | |
| | First light emitting | RED Host:RED | 250 | |
| | layer (red) | Dopant | | |
| | First hole transport | NPB | Green: 450 | |
| | layer | | Blue: 930 | |
| | | | Red: 1130 | |
| | First hole injection | TAPC:HATCN | 50 | |
| | layer | | | |

| | | |
|---|---|---|
| First electrode | ITO/Ag/ITO | 70/800/70 |

As shown in Table 3, a thickness of the first hole transport layer of the light emitting diode may vary according to a pixel included in each light emitting diode. That is, the light emitting diode included in a green pixel may have the first hole transport layer with a thickness of 450 Å, the light emitting diode included in a blue pixel may have the first hole transport layer with a thickness of 930 Å, and the light emitting diode included in a red pixel may have the first hole transport layer with a thickness of 1130 Å. By varying a thickness of the first hole transport layer for each pixel as described above, an optimal resonance thickness for each pixel may be derived. Table 4 shows a stacking structure of the light emitting diode according to another embodiment. Table 4 shows a material, a thickness, and a doping concentration included in each layer constituting the light emitting diode LED1, LED2, LED3, LED4, or LED5. However, this is only an example, and the disclosure is not limited thereto.

TABLE 4

| | | | | Doping |
|---|---|---|---|---|
| | | | | concentration |
| Layer | | Material name | Thickness (Å) | (%) |
| Second electrode | | CPL | 500 | |
| | | AgMg | 100 | 10 |
| | | Yb | 10 | |
| LED5 | Fifth electron | TPM-TAZ + Liq | 570 | 50 |
| | transport layer | | | |
| | Fifth light emitting | GH_HT:GH_ET 1:1 + | 250 | 9 |
| | layer (green) | GD | | |
| | Fifth hole transport | NPB | 300 | |
| | layer | | | |
| | Fifth hole injection | HATCN | 50 | |
| | layer | | | |
| CGL | | BCP + Li | 65 | 10 |
| LED4 | Fourth electron | TPM-TAZ + Liq | 100 | 50 |
| | transport layer | | | |
| | Fourth hole | T2T | 50 | |
| | blocking layer | | | |
| | Fourth light | BH1 (or BH2) + BD | 85 | 1 |
| | emitting layer | | | |
| | (blue) | | | |
| | Fourth electron | TCTA | 75 | |
| | blocking layer | | | |
| | Fourth hole | NPB | 20 | |
| | transport layer | | | |
| | Fourth hole | HATCN | 50 | |
| | injection layer | | | |
| CGL | | BCP + Li | 65 | 10 |
| LED3 | Third electron | TPM-TAZ + Liq | 100 | 50 |
| | transport layer | | | |
| | Third light emitting | GH_HT:GH_ET 1:1 + | 200 | 9 |
| | layer (green) | GD | | |
| | Third hole | NPB | 85 | |
| | transport layer | | | |
| | Third hole injection | HATCN | 50 | |
| | layer | | | |
| CGL | | BCP + Li | 65 | 10 |
| LED2 | Second electron | TPM-TAZ + Liq | 100 | 50 |
| | transport layer | | | |
| | Second hole | T2T | 50 | |
| | blocking layer | | | |
| | Second light | BH1 (or BH2) + BD | 85 | 1 |
| | emitting layer | | | |
| | (blue) | | | |
| | Second electron | TCTA | 75 | |
| | blocking layer | | | |
| | Second hole | NPB | 370 | |
| | transport layer | | | |
| | Second hole | HATCN | 50 | |
| | injection layer | | | |
| CGL | | BCP + Li | 65 | 10 |
| LED1 | First electron | TPM-TAZ + Liq | 100 | 50 |
| | transport layer | | | |
| | First hole blocking | T2T | 50 | |
| | layer | | | |
| | First light emitting | RED Host:RED | 250 | |
| | layer (red) | Dopant | | |
| | First hole transport | NPB | 1000 | |
| | layer | | | |
| | First hole injection | NPB + HATCN | Green: 400 | 10 |
| | layer | | Blue: 880 | |
| | | | Red: 1080 | |

| | | |
|---|---|---|
| First electrode | ITO/Ag/ITO | 70/800/70 |

As shown in Table 4, a thickness of the first hole injection layer of the light emitting diode may vary according to a pixel included in each light emitting diode. That is, the light emitting diode included in a green pixel may have the first hole transport layer with a thickness of 400 Å, the light emitting diode included in a blue pixel may have the first hole transport layer with a thickness of 880 Å, and the light emitting diode included in a red pixel may have the first hole transport layer with a thickness of 1080 Å. By varying a thickness of the first hole injection layer for each pixel as described above, an optimal resonance thickness for each pixel may be derived.

In the embodiment of Table 4, the first hole injection layer may include 10% of HATCN in NPB. In this case, the first hole injection layer may be formed by a deposition process or a solution process. Additionally, when the first hole injection layer is formed by the solution process, the first hole injection layer may include a PEDOT:PSS compound as shown below. However, this is only an example, and the disclosure is not limited thereto.

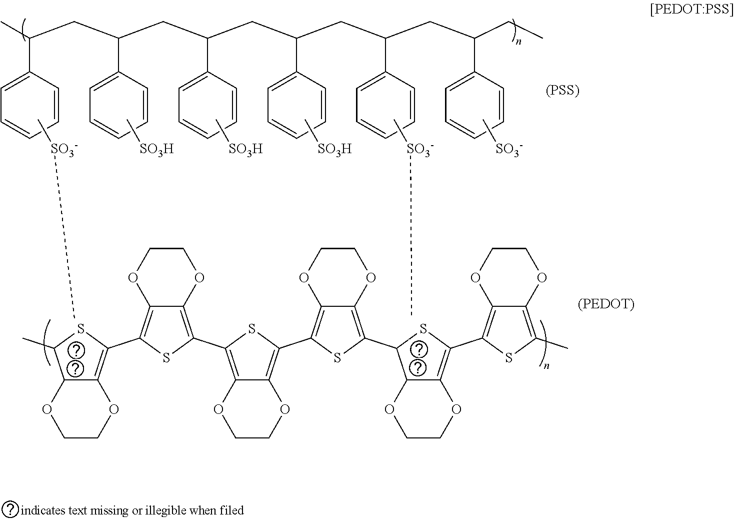

Table 5 shows a stacking structure of the light emitting diode according to another embodiment. In the light emitting diode according to the embodiment of the following Table 5, the first electrode, the blue-light emitting layer, the blue-light emitting layer, the green-light emitting layer, the blue-light emitting layer, the green-light emitting layer, and the second electrode are sequentially stacked, and the structure may be referred to as a BBGBG stacking structure.

TABLE 5

| | | | | Doping |
|---|---|---|---|---|
| | | | | concentration |
| Layer | | Material name | Thickness (Å) | (%) |
| Second electrode | | CPL | 500 | |
| | | AgMg | 100 | 10 |
| | | Yb | 10 | |
| LED5 | Fifth electron | TPM-TAZ + Liq | 570 | 50 |
| | transport layer | | | |
| | Fifth light emitting | GH_HT:GH_ET 1:1 + | 250 | 9 |
| | layer (green) | GD | | |
| | Fifth hole transport | NPB | 300 | |
| | layer | | | |
| | Fifth hole injection | HATCN | 50 | |
| | layer | | | |
| CGL | | BCP + Li | 65 | 10 |
| LED4 | Fourth electron | TPM-TAZ + Liq | 100 | 50 |
| | transport layer | | | |
| | Fourth hole | T2T | 50 | |
| | blocking layer | | | |
| | Fourth light | BH1 (or BH2) + BD | 85 | 1 |
| | emitting layer | | | |
| | (blue) | | | |
| | Fourth electron | TCTA | 75 | |
| | blocking layer | | | |
| | Fourth hole | NPB | 20 | |
| | transport layer | | | |
| | Fourth hole | HATCN | 50 | |
| | injection layer | | | |
| CGL | | BCP + Li | 65 | 10 |
| LED3 | Third electron | TPM-TAZ + Liq | 100 | 50 |
| | transport layer | | | |
| | Third light emitting | GH_HT:GH_ET 1:1 + | 200 | 9 |
| | layer (green) | GD | | |
| | Third hole | NPB | 85 | |
| | transport layer | | | |
| | Third hole injection | HATCN | 50 | |
| | layer | | | |
| CGL | | BCP + Li | 65 | 10 |
| LED2 | Second electron | TPM-TAZ + Liq | 100 | 50 |
| | transport layer | | | |
| | Second hole | T2T | 50 | |
| | blocking layer | | | |
| | Second light | BH1 (or BH2) + BD | 85 | 1 |
| | emitting layer | | | |
| | (blue) | | | |
| | Second electron | TCTA | 75 | |
| | blocking layer | | | |
| | Second hole | NPB | 370 | |
| | transport layer | | | |
| | Second hole | HATCN | 50 | |
| | injection layer | | | |
| CGL | | BCP + Li | 65 | 10 |
| LED1 | First electron | TPM-TAZ + Liq | 100 | 50 |
| | transport layer | | | |
| | First hole blocking | T2T | 50 | |
| | layer | | | |
| | First light emitting | RED Host:RED | 250 | |
| | layer (red) | Dopant | | |
| | First hole transport | NPB | 450 | |
| | layer | | | |
| | First hole injection | TAPC:HATCN | 50 | |
| | layer | | | |

| | | |
|---|---|---|
| First electrode | ITO/Ag/ITO | 70/800/70 |

The materials shown in Tables 1 to 5 are general materials, and chemical formulas of some of the materials are as follows. A material whose chemical formula is not shown corresponds to a common name of the material. Some chemical formulas describe a layer where a compound of the chemical formula is disposed.

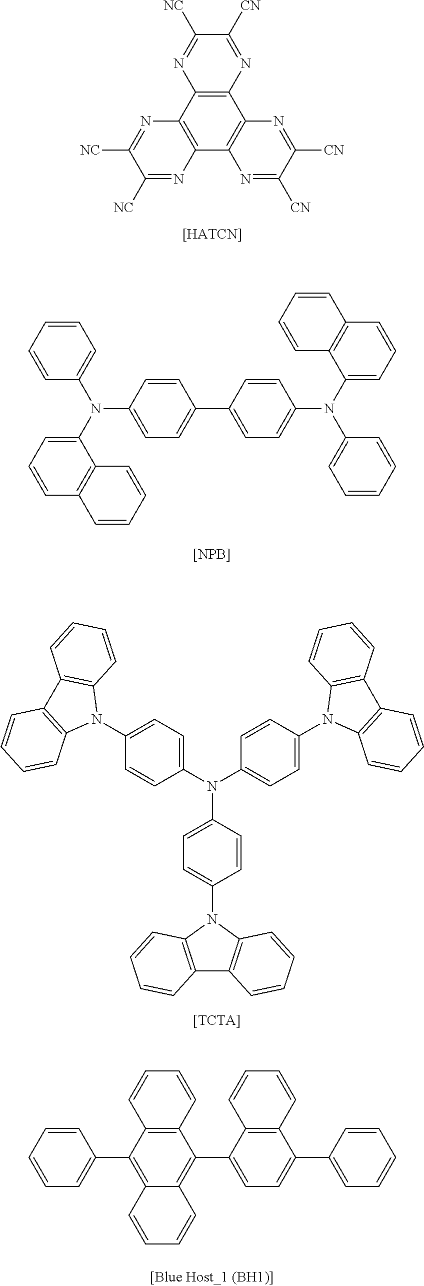

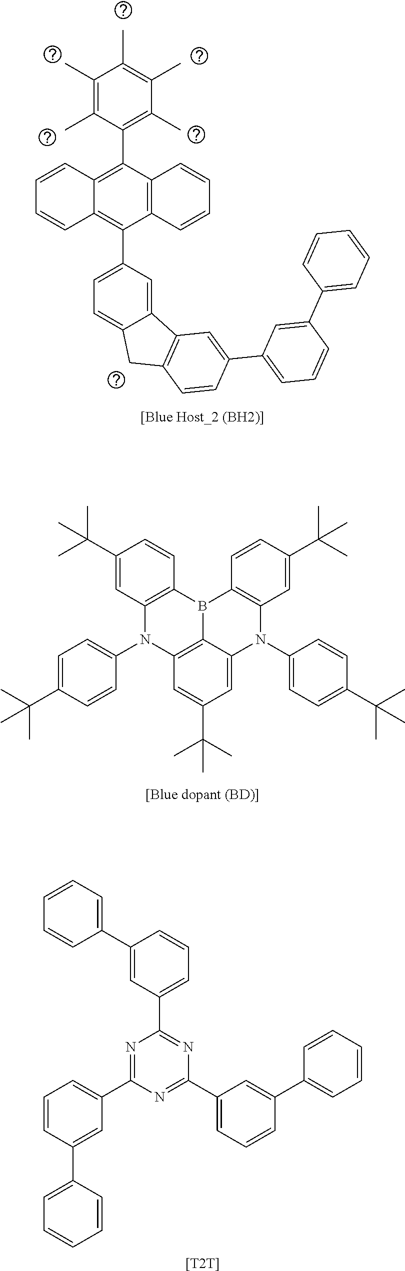

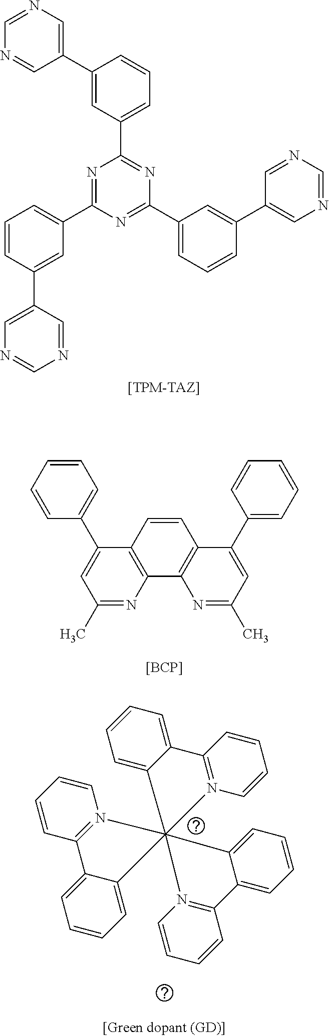

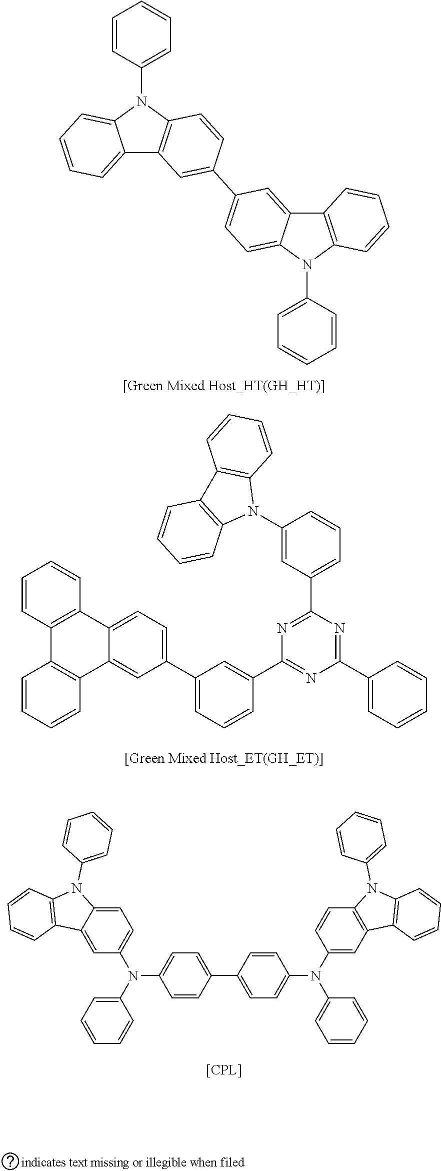 [SMILES: c1ccc(-n2c3ccccc3c3cc(-c4ccc5c(c4)c4ccccc4n5-c4ccccc4)ccc32)cc1 ; c1ccc(-c2nc(-c3cccc(-c4ccc5c6ccccc6c6ccccc6c5c4)c3)nc(-c3cccc(-n4c5ccccc5c5ccccc54)c3)n2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

In Tables 1 to 4, RED DOPANT of the first light emitting layer may be at least one selected from compounds described below. However, this is only an example, and the disclosure is not limited thereto.

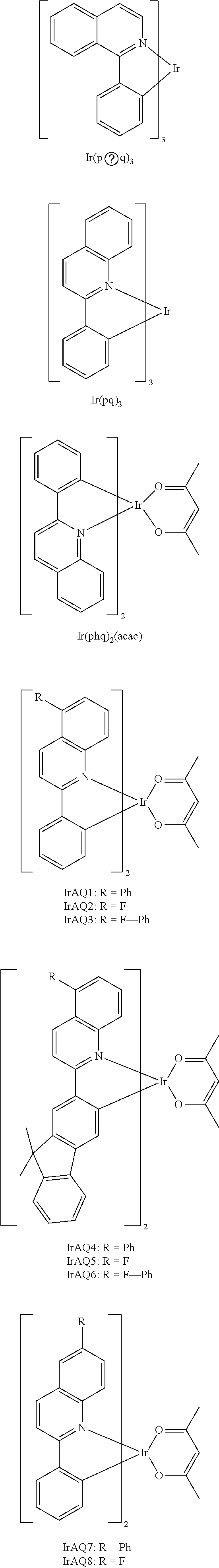

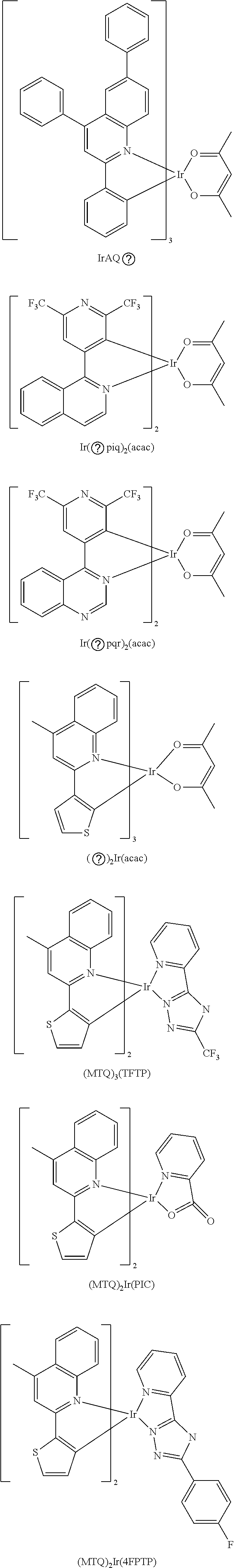

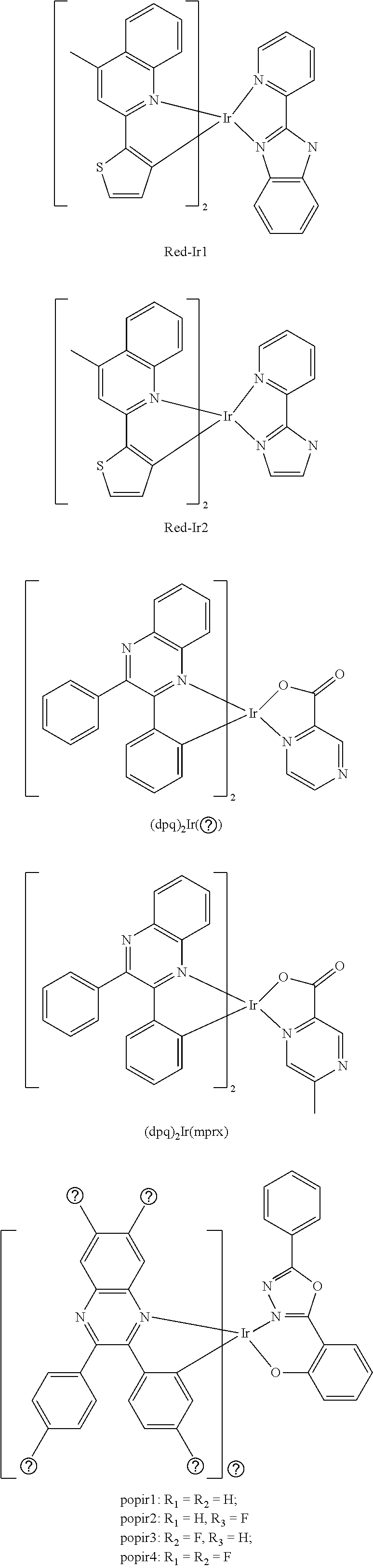

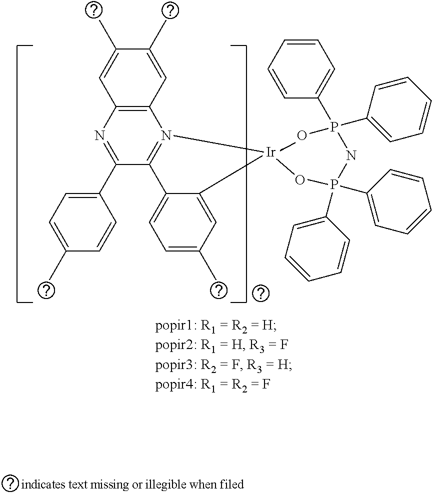

In Tables 1 to 4, RED HOST of the first light emitting layer may be at least one selected from compounds described below. However, this is only an example, and the disclosure is not limited thereto.

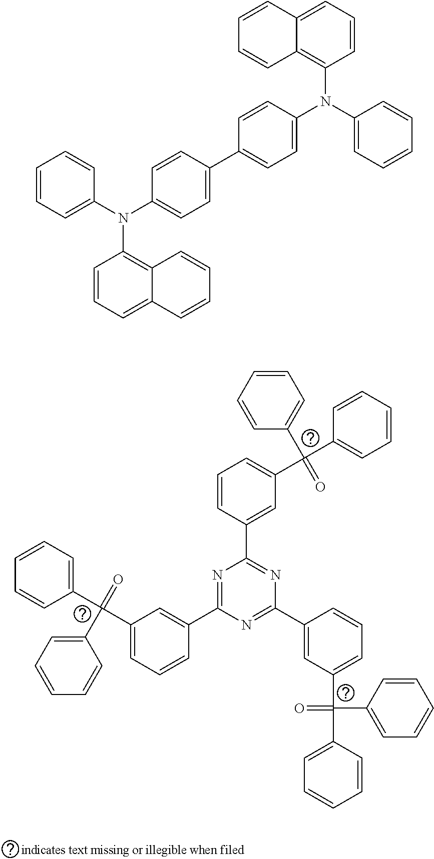

As will be described later, according to an embodiment, the light emitting diodes of Tables 1 to 4 having the RBGBG stacking structure may have improved luminance compared with the light emitting diode of Table 5 having the BBGBG stacking structure.

Hereinafter, the display device to which the light emitting diode according to an embodiment is applied will be described.

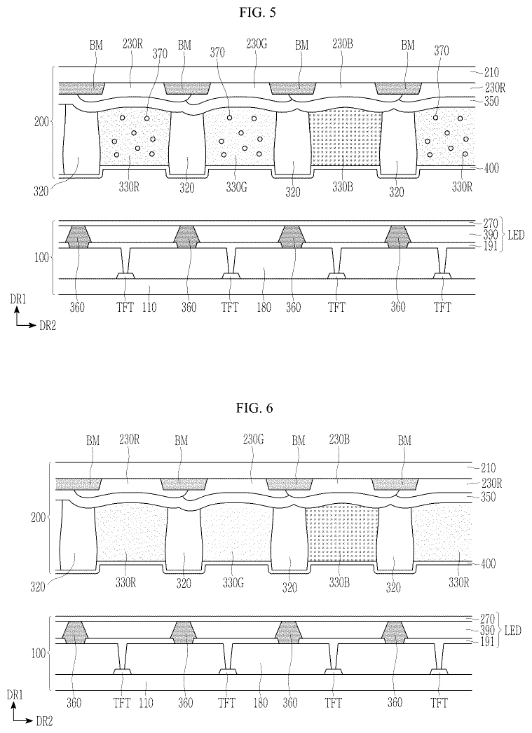

FIG. 5 shows a cross-section of the display device according to an embodiment. Referring to FIG. 5, the display device according to an embodiment may include a display panel 100 and a color conversion panel 200.

The display panel 100 may include a first substrate 110, and a plurality of transistors TFT and an insulating film 180 disposed on the first substrate 110. The first electrode 191 and a partition wall 360 may be disposed on the insulating film 180, and the first electrode 191 may be disposed in an opening portion of the partition wall 360 and may be connected to the transistor TFT. Although not specifically shown in the drawings, the transistor TFT may include a semiconductor layer, a source electrode and a drain electrode connected to the semiconductor layer, and a gate electrode insulated from the semiconductor layer. The second electrode 270 may be disposed on the partition wall 360, and a light emitting diode layer 390 may be disposed between the first electrode 191 and the second electrode 270. The first electrode 191, the second electrode 270, and the light emitting diode layer 390 are collectively referred to as a light emitting diode LED. In an embodiment, as described above with reference to FIG. 1, the light emitting diode LED may include or be defined by a stacked structure of the light emitting diodes LED1, LED2, LED3, LED4, and LED5. In such an embodiment, although not shown in FIG. 5, the light emitting diode LED may include the light emitting diodes LED1, LED2, LED3, LED4, and LED5 that emit light of different colors.

In an embodiment, the partition wall 360 may include a black material to effectively prevent color mixing between adjacent light emitting diodes LED. However, this is only an example, and the partition wall 360 may not include the black material in another embodiment.

In an embodiment, the color conversion panel 200 may include a second substrate 210 and a light blocking member BM disposed on the second substrate 210. The light blocking member BM may define a plurality of opening portions. Each of a first color filter 230R, a second color filter 230G, and a third color filter 230B may be disposed in a corresponding one of the opening portions of the light blocking member BM. The first color filter 230R may be a red color filter, the second color filter 230G may be a green color filter, and the third color filter 230B may be a blue color filter. However, this is only an example, and the disclosure is not limited thereto. Although an embodiment including the light blocking member BM is shown in FIG. 5, in another embodiment, a stacked structure in which the first color filter 230R, the second color filter 230G, and the third color filter 230B are stacked may be disposed instead of the light blocking member BM.

A planarization layer 350 may be disposed on the first color filter 230R, the second color filter 230G, and the third color filter 230B. The planarization layer 350 may planarize a surface of the color filter 230 while preventing direct contact between the color filter 230 and a color conversion layer and a transmission layer. According to another embodiment, the planarization layer 350 may be omitted.

A bank 320 may be disposed on the planarization layer 350. Banks 320 may be spaced apart from each other with a plurality of openings defined therebetween, and each opening may overlap a corresponding one of the color filters 230R, 230G, and 230B in a direction perpendicular to a surface of the first substrate 110.

A red color conversion layer 330R, a green color conversion layer 330G, and a transmission layer 330B may be disposed in a region between the banks 320 that are spaced apart from each other. A capping layer 400 may be disposed on the red color conversion layer 330R, the green color conversion layer 330G, and the transmission layer 330B.

The red color conversion layer 330R may convert blue light applied thereto into red. The green color conversion layer 330G may convert the blue light applied thereto into green. The red color conversion layer 330R and the green color conversion layer 330G may include a quantum dot.

Hereinafter, the quantum dot will be described in detail.

In the disclosure, the quantum dot (hereinafter also referred to as a semiconductor nanocrystal) may include a group II-VI compound, a group III-V compound, a group IV-VI compound, a group IV element or compound, a group I-III-VI compound, a group II-III-VI compound, a group I-II-IV-VI compound, or a combination thereof.

The group II-VI compound may be selected from a two-element compound selected from CdSe, CdTe, ZnS, ZnSe, ZnTe, ZnO, HgS, HgSe, HgTe, MgSe, MgS, and a mixture thereof; a three-element compound selected from AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a four-element compound selected from HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The group II-VI compound may further include a group III metal.

The group III-V compound may be selected from a two-element compound selected from GaN, GaP, GaAs, GaSb, AlN, AlP, AlAs, AlSb, InN, InP, InAs, InSb, and a mixture thereof; a three-element compound selected from GaNP, GaNAs, GaNSb, GaPAs, GaPSb, AlNP, AlNAs, AlNSb, AIPAS, AlPSb, InGaP, InNP, InNAs, InNSb, InPAs, InZnP, InPSb, and a mixture thereof; and a four-element compound selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and a mixture thereof. The group III-V compound may further include a group II metal (e.g., InZnP).

The group IV-VI compound may be selected from a two-element compound selected from SnS, SnSe, SnTe, PbS, PbSe, PbTe, and a mixture thereof; a three-element compound selected from SnSeS, SnSeTe, SnSTe, PbSeS, PbSeTe, PbSTe, SnPbS, SnPbSe, SnPbTe, and a mixture thereof; and a four-element compound selected from SnPbSSe, SnPbSeTe, SnPbSTe, and a mixture thereof.

The group IV element or compound may be selected from a one-element compound selected from Si, Ge, and a combination thereof; and a two-element compound selected from SiC, SiGe, and a combination thereof, but the disclosure is not limited thereto.

An example of the group I-III-VI compound may include CuInSe₂, CuInS₂, CuInGaSe, or CuInGaS, but the disclosure is not limited thereto. An example of the group I-II-IV-VI compound may include CuZnSnSe or CuZnSnS, but the disclosure is not limited thereto. The group IV element or compound may be selected from a one-element compound selected from Si, Ge, and a mixture thereof; and a two-element compound selected from SiC, SiGe, and a mixture thereof.

The group II-III-VI compound may be selected from ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and a combination thereof, but the disclosure is not limited thereto.

The group I-II-IV-VI compound may be selected from CuZnSnSe and CuZnSnS, but the disclosure is not limited thereto.

In an embodiment, the quantum dot may not include cadmium. The quantum dot may include a semiconductor nanocrystal based on a group III-V compound including indium and phosphorus. The group III-V compound may further include zinc. The quantum dot may include a semiconductor nanocrystal based on a group II-VI compound including a chalcogen element (e.g., sulfur, selenium, tellurium, or a combination thereof) and zinc.

In the quantum dot, the two-element compound, the three-element compound, and/or the four-element compound may exist within a particle with a uniform concentration, or may exist within the same particle by being divided into states with different partial concentration distributions. The quantum dot may have a core/shell structure in which one quantum dot surrounds the other quantum dot. An interface between the core and the shell may have a concentration gradient in which a concentration of an element present in the shell decreases toward a center thereof.

In some embodiments, the quantum dot may have a core-shell structure including a core including the nanocrystal and a shell surrounding the core. The shell of the quantum dot may serve as a protective layer for maintaining a semiconductor characteristic by preventing chemical denaturation of the core and/or a charging layer for imparting an electrophoretic characteristic to the quantum dot. The shell may be a single layer or multiple layers. An interface between the core and the shell may have a concentration gradient in which a concentration of an element present in the shell decreases toward a center thereof. An example of the shell of the quantum dot may include metal oxide, non-metal oxide, a semiconductor compound, or a combination thereof.

For example, the metal oxide or the non-metal oxide may be a two-element compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a three-element compound such as MgAl₂O₄, CoFe₂O₄, NiFe₂O₄, or CoMn₂O₄, but the disclosure is not limited thereto.

The semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, but the disclosure is not limited thereto.

An interface between the core and the shell may have a concentration gradient in which a concentration of an element present in the shell decreases toward a center thereof. The semiconductor nanocrystal may have a structure including one semiconductor nanocrystal core and a multilayer shell surrounding the semiconductor nanocrystal core. In an embodiment, the multilayer shell may have two or more layers (for example, two, three, four, five, or more layers). Two adjacent layers of the shell may have a single composition or different compositions. Each layer of the multilayer shell may have a composition that varies along a radius thereof.

The quantum dot may have a full width at half maximum (FWHM) (e.g., about 45 nanometers (nm) or less, about 40 nm or less, or about 30 nm or less) of a light emitting wavelength spectrum, and may improve color purity or color reproducibility within a range of the full width at half maximum. Additionally, because light emitted through the quantum dot is emitted in all directions, a viewing angle may be improved.

In the quantum dot, a material of the shell and a material of the core may have different energy bandgaps. For example, the energy bandgap of the material of the shell may be larger than that of the material of the core. In another embodiment, the energy bandgap of the material of the shell may be smaller than that of the material of the core. The quantum dot may have a multilayer shell. In the multilayer shell, an energy bandgap of an outer layer thereof may be larger than an energy bandgap of an inner layer thereof (i.e., a layer closer to the core). In the multilayer shell, the energy bandgap of the outer layer may be smaller than the energy bandgap of the inner layer.

The quantum dot may adjust an absorption/emission wavelength by adjusting a composition and a size thereof. A maximum light emitting peak wavelength of the quantum dot may have an ultraviolet or infrared wavelength or a wavelength range greater than or equal to the ultraviolet or infrared wavelength.

For example, the quantum dot may have a quantum efficiency of about 10% or greater, about 30% or greater, about 50% or greater, about 60% or greater, about 70% or greater, about 90% or greater, or even about 100%. The quantum dot may have a relatively narrow spectrum. For example, the quantum dot may have a full width at half maximum (e.g., about 50 nm or less, about 45 nm or less, about 40 nm or less, or about 30 nm or less) of a light emitting wavelength spectrum.

The quantum dot may have a particle size greater than or equal to about 1 nm and less than or equal to about 100 nm. The size of the particle refers to a diameter of the particle or a diameter converted by assuming a spherical shape from a two-dimensional image obtained by transmission electron microscope analysis. For example, the quantum dot may have a size of about 1 nm to about 20 nm (e.g., 2 nm or greater, 3 nm or greater, or 4 nm or greater), 50 nm or less, 40 nm or less, 30 nm or less, 20 nm or less, 15 nm or less, or 10 nm or less. A shape of the quantum dot is not particularly restricted. For example, the shape of the quantum dot may include a sphere, a polyhedron, a pyramid, a multi-pod, a square, a rectangular parallelepiped, a nanotube, a nanorod, a nanowire, a nanosheet, or a combination thereof, but the disclosure is not limited thereto.

The quantum dot may be commercially available or appropriately synthesized. The quantum dot may adjust the particle size relatively freely or uniformly during colloidal synthesis.

The quantum dots may include an organic ligand (e.g., the organic ligand having a hydrophobic residue and/or a hydrophilic residue). A residue of the organic ligand may be coupled to a surface of the quantum dot. The organic ligands may include RCOOH, RNH₂, R₂NH, R₃N, RSH, R₃PO, R₃P, ROH, RCOOR, RPO(OH)₂, RHPOOH, R₂POOH, or a combination thereof, wherein each R may be independently a C₃ to C₄₀ substituted or unsubstituted aliphatic hydrocarbon group (e.g., C₃ to C₄₀ or C₅ to C₂₄ substituted or unsubstituted alkyl, C₃ to C₄₀ or C₅ to C₂₄ substituted or unsubstituted alkenyl, or the like), a C₆ to C₄₀ or C₆ to C₂₀ substituted or unsubstituted aromatic hydrocarbon group (e.g., a C₆ to C₄₀ substituted or unsubstituted aryl group or the like), or a combination thereof.

An example of the organic ligand may be a thiol compound such as methane thiol, ethane thiol, propane thiol, butane thiol, pentane thiol, hexane thiol, octane thiol, dodecane thiol, hexadecane thiol, octadecane thiol, or benzyl thiol; an amine compound such as methane amine, ethane amine, propane amine, butane amine, pentyl amine, hexyl amine, octyl amine, nonyl amine, decyl amine, dodecyl amine, hexadecyl amine, octadecyl amine, dimethyl amine, diethyl amine, dipropyl amine, tributyl amine, or trioctyl amine; a carboxylic acid compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, or benzoic acid; a phosphine compound such as methyl phosphine, ethyl phosphine, propyl phosphine, butyl phosphine, pentyl phosphine, octyl phosphine, dioctyl phosphine, tributyl phosphine, or trioctyl phosphine; a phosphine compound or an oxide compound thereof such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, or trioctyl phosphine oxide; a diphenyl phosphine compound, a triphenyl phosphine compound, or an oxide compound thereof; or a C₅ to C₂₀ alkyl phosphinic acid such as hexyl phosphinic acid, octyl phosphinic acid, dodecane phosphinic acid, tetradecane phosphinic acid, hexadecane phosphinic acid, or octadecane phosphinic acid or a C₅ to C₂₀ alkyl phosphonic acid, but the disclosure is not limited thereto. The quantum dot may include a hydrophobic organic ligand alone or as a mixture of one or more. The hydrophobic organic ligand may not include a photopolymerizable residue (e.g., an acrylate group, a methacrylate group, or the like).

The red color conversion layer 330R and the green color conversion layer 330G may include a scatterer 370. The scatterer 370 may include at least one selected from SiO₂, BaSO₄, Al₂O₃, ZnO, ZrO₂, and TiO₂. The scatterer may increase light emitting efficiency by scattering light emitted from the light emitting diode layer 390. In an embodiment, the transmission layer 330B may not include a scatterer. In such an embodiment, light absorption by the scatterer may be effectively prevented such that efficiency of blue light is improved.

In another embodiment, the red color conversion layer 330R and the green color conversion layer 330G may not include a scatterer. FIG. 6 shows a cross-section of a display device according to another embodiment corresponding to that of FIG. 5. Referring to FIG. 6, the display device according to another embodiment is the same as the embodiment of FIG. 5 except that all of the transmission layer 330B, the red color conversion layer 330R, and the green color conversion layer 330G do not include the scatterer. Accordingly, any detailed description of the same components as those described above will be omitted.

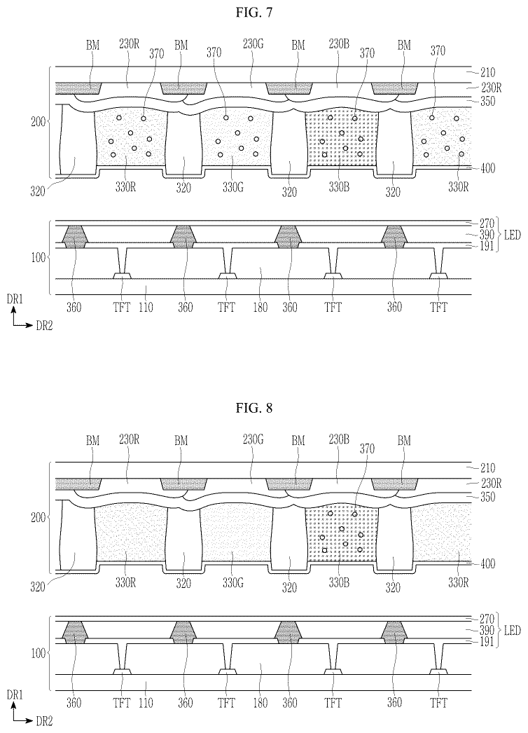

In a display device according to another embodiment, the transmission layer 330B may include a scatterer. FIG. 7 shows a cross-section of the display device according to another embodiment. Referring to FIG. 7, the display device according to another embodiment is the same as the embodiment of FIG. 5 except that the transmission layer 330B includes the scatterer. Accordingly, any repetitive detailed description of the same components as those described above will be omitted.

In another embodiment, as shown in FIG. 7, the transmission layer 330B may include a scatterer, and the red color conversion layer 330R and the green color conversion layer 330G may also not include a scatterer. FIG. 8 shows of the display device according to another embodiment corresponding to that of FIG. 7. Referring to FIG. 8, the display device according to another embodiment is the same as the embodiment of FIG. 7 except that the red color conversion layer 330R and the green color conversion layer 330G do not include the scatterer. Accordingly, any repetitive detailed description of the same components as those described above will be omitted.

Hereinafter, a light emitting diode and a display device including the light emitting diode according to an embodiment will be described.

The following Table 6 shows a result of measuring efficiency of each color and luminance when the light emitting diode having the stacking structure according to the embodiments corresponding to (or having structures or features of) Table 1 and Table 5 is applied to the display device having the structure of FIG. 6 in which the transmission layer includes the scatterer.

TABLE 6

| | | Efficiency | Efficiency | Efficiency | Efficiency | |
|---|---|---|---|---|---|---|
| Structure of | Structure | of red | of green | of blue | of white | |
| display device | of diode | light | light | light | light | Luminance |
| Display device of | Table 5 | 100% | 100% | 100% | 100% | 1500 nit |
| FIG. 6 in which | (BBGBG) | (reference) | (reference) | (reference) | | |
| transmission layer | | | | | | |
| includes scatterer | | | | | | |
| Display device of | Table 1 | 172% | 90% | 70% | 90% | 1500 nit |
| FIG. 6 in which | (RBGBG) | | | | | |
| transmission layer | | | | | | |
| includes scatterer | | | | | | |

Referring to Table 6 above, the embodiment corresponding to Table 1 has improved the efficiency of red light, and slightly reduced the efficiency of blue light. Although the efficiency of white light of the embodiment corresponding to Table 1 is decreased compared with that of the embodiment corresponding to Table 5, it may be confirmed that overall luminance is maintained. The following Table 7 shows a result of measuring efficiency of each color and luminance when the light emitting diode having the stacking structure according to the embodiment corresponding to Table 5 is applied to the display device of FIG. 5 in which the transmission layer does not include the scatterer.

TABLE 7

| | | Efficiency | Efficiency | Efficiency | Efficiency | |
|---|---|---|---|---|---|---|
| Structure of | Structure | of red | of green | of blue | of white | |
| display device | of diode | light | light | light | light | Luminance |
| Display device of | Table 5 | 100% | 100% | 200% | 121% | 1500 nit |
| FIG. 5 in which | (BBGBG) | | | | | |
| transmission layer | | | | | | |
| does not include | | | | | | |
| scatterer | | | | | | |
| Display device of | Table 1 | 172% | 90% | 140% | 135% | 1500 nit |
| FIG. 5 in which | (RBGBG) | | | | | |
| transmission layer | | | | | | |
| does not include | | | | | | |
| scatterer | | | | | | |
| Display device of | Table 2 | 200% | 300% | 140% | 230% | 1500 nit |
| FIG. 5 in which | (RBGBG: | | | | | |
| transmission layer | differential | | | | | |
| does not include | ITO structure) | | | | | |
| scatterer | | | | | | |
| Display device of | Table 3 | 210% | 295% | 130% | 220% | 1500 nit |
| FIG. 5 in which | (RBGBG: | | | | | |
| transmission layer | differential | | | | | |
| does not include | HTL structure) | | | | | |
| scatterer | | | | | | |
| Display device of | Table 4 | 205% | 290% | 130% | 215% | 1500 nit |
| FIG. 5 in which | (RBGBG: | | | | | |
| transmission layer | differential | | | | | |
| does not include | HIL structure) | | | | | |
| scatterer | | | | | | |

Referring to Table 7, the light emitting diode (RBGBG) with the structure shown in Table 1 has improved efficiency of red light and slightly reduced efficiency of blue light. However, it may be confirmed that the efficiency of white light of the embodiment corresponding to Table 1 is improved compared with that of the light emitting diode (BBGBG) with the embodiment having the structure of Table 5. This is because the display device having the structure of FIG. 5 in which the transmitting layer does not include the scatterer may reduce absorption of blue light by the scatterer. Therefore, when white light is emitted, light emitting efficiency of white light may be improved. In Table 7, the efficiency of blue light of the embodiment corresponding to Table 1 is decreased compared with that of the embodiment of Table 5, but because white light emits a combination of green light, red light, and blue light, overall light emitting efficiency of white light may increase in the embodiment corresponding to Table 1. It may be confirmed that efficiency of blue light, efficiency of red light, and efficiency of green light in the embodiments corresponding to Table 2 to Table 4 having differential ITO structure, differential HTL structure, or differential HIL structure for each pixel are all improved compared with those of the embodiment corresponding to Table 5. In addition, the light emitting efficiency of white light is significantly improved compared with the embodiment corresponding to Table 5.

As described above, the light emitting diode according to embodiments may include five light emitting layers, and the light emitting layers may include one red-light emitting layer, two green-light emitting layers, and two blue-light emitting layers. The light emitting diode may improve light emitting efficiency. In embodiments of the display device to which the light emitting diode is applied, the transmission layer may not include a scatterer, and light emitting efficiency may be improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A light emitting diode, comprising:
a first electrode;
a second electrode disposed opposite to the first electrode; and
a plurality of light emitting layers disposed between the first electrode and the second electrode,
wherein the light emitting layers comprise one red-light emitting layer, two green-light emitting layers, and two blue-light emitting layers.

2. The light emitting diode of claim 1, wherein the light emitting layers are stacked in an order of the one red-light emitting layer, one of the two blue-light emitting layers, one of the two green-light emitting layers, the other of the two blue-light emitting layers, and the other of the two green-light emitting layers between the first electrode and the second electrode.

3. The light emitting diode of claim 1, wherein the light emitting layers are stacked in an order of one of the two blue-light emitting layers, the one red-light emitting layer, one of the two green-light emitting layers, the other of the two blue-light emitting layers, and the other of the two green-light emitting layers between the first electrode and the second electrode.

4. The light emitting diode of claim 1, wherein the light emitting layers are stacked in an order of one of the two blue-light emitting layers, the other of the two blue-light emitting layers, one of the two green-light emitting layers, the one red-light emitting layer, and the other of the two green-light emitting layers between the first electrode and the second electrode.

5. The light emitting diode of claim 1, wherein an entire thickness of all layers disposed between the first electrode and the second electrode is in a range of about 3800 Å to about 4800 Å.

6. A display device comprising:
a color conversion panel; and
a display panel disposed to overlap the color conversion panel,
wherein the display panel comprises a first substrate and a plurality of light emitting diodes disposed above the first substrate,
the color conversion panel comprises a first color conversion layer, a second color conversion layer, and a transmission layer which are disposed to overlap the light emitting diodes, respectively,
the transmission layer does not include a scatterer,
each of the light emitting diodes comprises a first electrode, a second electrode disposed opposite to the first electrode, and a plurality of light emitting layers disposed between the first electrode and the second electrode, and
the light emitting layers comprise one red-light emitting layer, two green-light emitting layers, and two blue-light emitting layers.

7. The display device of claim 6, wherein the light emitting layers are stacked in an order of the one red-light emitting layer, one of the two blue-light emitting layers, one of the two green-light emitting layers, the other of the two blue-light emitting layers, and the other of the two green-light emitting layers between the first electrode and the second electrode.

8. The display device of claim 6, wherein the light emitting layers are stacked in an order of one of the two blue-light emitting layers, the one red-light emitting layer, one of the two green-light emitting layers, the other of the two blue-light emitting layers, and the other of the two green-light emitting layers between the first electrode and the second electrode.

9. The display device of claim 6, wherein the light emitting layers are stacked in an order of one of the two blue-light emitting layers, the other of the two blue-light emitting layers, one of the two green-light emitting layers, the one red-light emitting layer, and the other of the two green-light emitting layers between the first electrode and the second electrode.

10. The display device of claim 6, wherein an entire thickness of all layers disposed between the first electrode and the second electrode is in a range of about 3800 Å to about 4800 Å.

11. The display device of claim 6, wherein the color conversion panel further comprises a blue color filter, a red color filter, and a green color filter which are disposed to overlap the light emitting diodes, respectively.

12. The display device of claim 11, wherein thicknesses of first electrodes of the light emitting diodes which overlap the blue color filter, the red color filter, and the green color filter, respectively, are different from each other.

13. The display device of claim 11, wherein each of the light emitting diodes further comprises a hole transport layer and a hole injection layer, and
thicknesses of hole transport layers or hole injection layers of the light emitting diodes which overlap the blue color filter, the red color filter, and the green color filter, respectively, are different from each other.

14. A display device comprising:
a color conversion panel; and
a display panel disposed to overlap the color conversion panel,
wherein the display panel comprises a first substrate and a plurality of light emitting diodes disposed above the first substrate,
the color conversion panel comprises a first color conversion layer, a second color conversion layer, and a transmission layer which are disposed to overlap the light emitting diodes, respectively,
each of the light emitting diodes comprise a first electrode, a second electrode disposed opposite to the first electrode, and a plurality of light emitting layers disposed between the first electrode and the second electrode, and
the light emitting layers comprise one red-light emitting layer, two green-light emitting layers, and two blue-light emitting layers.

15. The display device of claim 14, wherein the light emitting layers are stacked in an order of the one red-light emitting layer, one of the two blue-light emitting layers, one of the two green-light emitting layers, the other of the two blue-light emitting layers, and the other of the two green-light emitting layers between the first electrode and the second electrode.

16. The display device of claim 14, wherein the light emitting layers are stacked in an order of one of the two blue-light emitting layers, the one red-light emitting layer, one of the two green-light emitting layers, the other of the two blue-light emitting layers, and the other of the two green-light emitting layers between the first electrode and the second electrode.

17. The display device of claim 14, wherein the light emitting layers are stacked in an order of one of the two blue-light emitting layers, the other of the two blue-light emitting layers, one of the two green-light emitting layers, the one red-light emitting layer, and the other of the two green-light emitting layers between the first electrode and the second electrode.

18. The display device of claim 14, wherein an entire thickness of all layers disposed between the first electrode and the second electrode is in a range of about 3800 Å to about 4800 Å.

19. The display device of claim 14, wherein thicknesses of first electrodes of the light emitting diodes which overlap the first color conversion layer, the second color conversion layer, and the transmission layer, respectively, are different from each other.

20. The display device of claim 14, wherein each of the light emitting diode further comprises a hole transport layer and a hole injection layer, and
thicknesses of hole transport layers or hole injection layers of the light emitting diodes which overlap the first color conversion layer, the second color conversion layer, and the transmission layer, respectively, are different from each other.
